(19) United States
(12) Patent Application Publication
(10) Pub. No.: US 2024/0023459 A1
(43) Pub. Date: Jan. 18, 2024

(54) MAGNETIC DEVICE HAVING PLURALITY OF COUPLED MAGNETIC TUNNEL JUNCTION PILLARS

(71) Applicants: IMEC VZW, Leuven (BE); Katholieke Universiteit Leuven, Leuven (BE)

(72) Inventors: Van Dai Nguyen, Wavre (BE); Eline Raymenants, Bonheiden (BE); Sebastien Couet, Grez-Doiceau (BE); Maxwel Gama Monteiro Junior, Leuven (BE); Bob Vermeulen, Huy (BE)

(21) Appl. No.: 18/351,308

(22) Filed: Jul. 12, 2023

(30) Foreign Application Priority Data
Jul. 13, 2022 (EP) 22184697.5

(51) Int. Cl. H10N 50/10; H10N 50/01; H10N 50/85; H10B 61/00; G11C 11/16

(52) U.S. Cl. CPC H10N 50/10; H10N 50/01; H10N 50/85; H10B 61/00; G11C 11/161

(57) ABSTRACT

A magnetic device may include at least two MTJ pillars, each MTJ pillar comprising a stack of a heavy metal layer portion, a second free magnetic layer portion, a spacer portion, a first free magnetic layer portion, a tunnel barrier layer portion, and a fixed magnetic layer portion, wherein at least the heavy metal layer portions, the second free magnetic layer portions and the spacer portions extend between the MTJ pillars through respectively an interconnecting heavy metal layer portion, an interconnecting second free magnetic layer portion and an interconnecting spacer portion, and wherein the interconnecting second free magnetic layer portion has an in-plane magnetization and the second free magnetic layer portions have an out-of-plane magnetization.

### CROSS-REFERENCE TO RELATED APPLICATIONS

This application claims foreign priority to European Patent Application 22184697.5, filed Jul. 13, 2022, the content of which is incorporated by reference herein in its entirety.

### BACKGROUND

### Field

This application relates generally to the field of semiconductor devices, and more particularly to magnetic devices having a plurality of coupled magnetic tunnel junction pillars that can be arranged as logic devices.

### Description of the Related Technology

Further scaling of complementary metal-oxide semiconductor (CMOS) technology is currently approaching fundamental limits. Therefore, there is an increasing demand to identify beyond-CMOS solutions to circumvent these challenges. Spin logic devices which exploit both the electron's charge and spin to perform logic operations are currently considered as a potential replacement. Spin logic devices are expected to enable functional scaling rather than dimensional scaling thanks to their special properties, such as non-volatility, ultra-low power consumption, and small footprint. Among them, the spin torque majority gate device (STMG) has been intensely studied since the last decade. However, there is a need for alternative solutions for magnetic devices and logic devices relative to the STMG studied to date.

### SUMMARY OF CERTAIN INVENTIVE ASPECTS

Some embodiments of the present disclosure may provide a magnetic device comprising a plurality of MTJ pillars. Some embodiments may provide a logic device comprising such a magnetic device. Some embodiments may provide a method for making such a magnetic device and/or such a logic device.

Some embodiments relate to a magnetic device comprising at least two magnetic tunnel junction (MTJ) pillars.

Each MTJ pillar may include a heavy metal layer portion, a second free magnetic layer portion on the heavy metal layer portion, a spacer portion on the second free magnetic layer portion, a first free magnetic layer portion on the spacer portion, a tunnel barrier layer portion on the first free magnetic layer portion, and a fixed magnetic layer portion on the tunnel barrier layer portion.

At least the heavy metal layer portions, the second free magnetic layer portions, and the spacer portions may extend between the MTJ pillars through, respectively, an interconnecting heavy metal layer portion, an interconnecting second free magnetic layer portion, and an interconnecting spacer portion, thus respectively forming a heavy metal layer, a second free magnetic layer, and a spacer layer.

The interconnecting second free magnetic layer portion may have an in-plane magnetization, and the second free magnetic layer portions of the MTJ pillars may have an out-of-plane magnetization.

Some embodiments may enable chiral coupling between perpendicular MTJ pillars that are interconnected via an in-plane free magnetic layer. This chiral coupling may be induced by Dzyaloshinskii-Moriya interaction (DMI) at the interface of the second free magnetic layer and the heavy metal layer.

In some embodiments, chiral coupling between the MTJ pillars interconnected via the in-plane free magnetic layer may allow transferring the magnetic information between the MTJ pillars via chiral induced switching. As a result, no in-plane current may be needed to drive the motion of domain walls (DWs) for information transmission. Therefore, it may offer faster operation and/or lower energy consumption and may overcome challenges related to domain wall motion and current crowding.

In some embodiments, spin transfer torque (STT) can be applied at an MTJ pillar to locally switch its magnetization state. In some embodiments, the change of magnetization state of an MTJ pillar may be electrically detected by tunneling magnetoresistance (TMR) read.

The spacer layer may make a structural transition between the first free magnetic layer portions and the second free magnetic layer. The thickness of the spacer layer (also referred to as an interexchange layer) may be tuned such that the first free magnetic layer portions and the second free magnetic layer are ferromagnetically coupled through exchange interaction.

Some embodiments relate to a logic device comprising a magnetic device as described herein. The magnetic device may include at least four MTJ pillars. In some embodiments, an odd number of pillars may be used as input and another pillar may be used as output. The pillars may be interconnected via the interconnecting in-plane free layer. Thus, a logic device implementation of chiral switching for minority gates operation may be obtained. Via STT, the magnetization state of one or more MTJ pillars can be controlled and the combined output can be retrieved via TMR on another MTJ pillar.

In a logic device according to some embodiments, the number of MTJs may, for example, be exactly four. In such embodiments, the arms may be positioned such that a T-shape is formed.

Some embodiments relate to a method for manufacturing a magnetic or logic device comprising at least two MTJ pillars. The method may include:
providing a heavy metal layer,
providing a second free magnetic layer on top of the heavy metal layer,
providing a spacer layer on the second free magnetic layer,
providing a first free magnetic layer on the spacer layer,
providing a tunnel barrier layer on the first free magnetic layer,
providing a fixed magnetic layer on the tunnel barrier layer,
structuring the fixed magnetic layer such that fixed magnetic layer portions of the MTJ pillars remain, thus subdividing the second free magnetic layer into second free magnetic layer portions underneath the fixed magnetic layer portions, and an interconnecting second free magnetic layer portion between two MTJ pillars, wherein the second free magnetic layer portions are out-of-plane magnetic regions, and
ion beam etching and/or ion irradiating between the fixed magnetic layer portions such that the interconnecting second free magnetic layer portion has an in-plane magnetic state.

Some embodiments relate to the use of a magnetic or logic device as described herein. Spin transfer torque may be used to drive switching of the first and the second free magnetic layer portions under one of the MTJ pillars. This may induce the switching of the interconnecting second free layer portion due to chiral coupling. Tunneling magnetoresistance may be used to read a magnetization of the first free magnetic layer portion of another of the MTJ pillars.

Particular embodiments are set out in the accompanying independent and dependent claims. Features from the dependent claims may be combined with features of the independent claims and with features of other dependent claims as appropriate and not merely as explicitly set out in the claims.

These and other aspects will be apparent from and elucidated with reference to the embodiment(s) described hereinafter.

### BRIEF DESCRIPTION OF THE DRAWINGS

FIG. 1 shows a schematic drawing of a hybrid free layer stack design and of a magnetic device comprising 2 MTJ pillars and an interconnecting free magnetic layer with in-plane magnetization according to some embodiments.

FIG. 2 schematically illustrates the operation of a magnetic device according to some embodiments.

FIG. 3 shows schematic drawings of a logic device comprising 3 MTJ inputs and 1 MTJ output according to some embodiments.

FIGS. 4a-4d schematically illustrate the operation of a logic device according to some embodiments.

FIG. 5 presents the schematic of a minority logic gate driven by chiral coupling according to some embodiments.

FIG. 6 shows a flow chart of a method for manufacturing a magnetic or logic device according to some embodiments.

FIG. 7 illustrates the structuring step of a method for manufacturing a magnetic device according to some embodiments.

FIG. 8 illustrates the ion beam etching/ion irradiation step for creating the in-plane magnetic state of the interconnecting second free magnetic layer, of a method according to some embodiments.

FIG. 9 illustrates an alternative method step for creating the in-plane magnetic state of the interconnecting second free magnetic layer, of a method according to some embodiments.

FIG. 10 shows magnetic properties of a MTJ stack, for which the thickness of the second free magnetic layer is about 0.67 nm.

FIG. 11 shows magnetic properties of a MTJ stack, for which the thickness of the second free magnetic layer is about 0.8 nm.

FIG. 12 shows a schematic drawing of a control structure which can be used to validate the in-plane magnetization after applying the method step for obtaining the in-plane magnetization according to some embodiments.

FIG. 13 and FIG. 14 show control structures wherein one MTJ pillar is coupled with an extended in-plan free layer according to some embodiments.

FIG. 15 shows a control structure for pricing chiral coupling with two MTJ pillars using an in-plane magnetic field according to some embodiments.

In the different drawings, the same reference signs refer to the same or analogous elements.

### DETAILED DESCRIPTION OF CERTAIN ILLUSTRATIVE EMBODIMENTS

An STMG device in which an AND gate and an OR gate are combined in a single majority gate could potentially reduce circuit complexity and therefore revolutionize circuit design. In some devices (see, e.g., Nikonov et al., IEEE Elec. Dev. Lett. 32, 1128-1130 (2011)), a functional STMG device is based on domain wall (DW) motion in a free layer shared by multiple magnetic tunnel junction (MTJ) pillars. The simplest design of majority gates has three inputs and one output. The output turns to ‘true’ if more than 50% of the inputs are ‘true’. In the STMG operation, domain walls which are generated by spin transfer torque (STT) at each input MTJ are driven in a complex shape of conduit layer by exchange interaction to perform the logic operation. The arrival of a domain wall at the output is probed by tunnelling magnetoresistance (TMR) at the output MTJ.

An STMG device which is based on exchange interaction driven domain wall motion in the free layer shared by multiple MTJ pillars requires ultra-scaled devices, since a dimension of devices is expected to be equivalent to the domain wall width, typically around 10 nm or below in a lateral dimension. High perpendicular magnetic anisotropy (PMA) materials are needed to maintain the magnetic properties of devices at low dimension, but it leads to very narrow domain wall width and thus small device dimension. Low PMA materials have larger domain wall widths which potentially enlarge the process window to fabricate these devices, but low PMA materials result in a loss of magnetic properties of devices due to the superparamagnetic effect. So far, there is no feasible solution for practical implementation of this device concept.

An STMG device may also be based on dipolar interaction. In this device concept, dipolar interaction between adjacent magnets has been proposed and demonstrated to perform majority logic operation (see, e.g., Lure et al., Science 311, 205-208 (2006)). However, this device proposal is difficult for scaling down at low dimension since the dipolar interaction strength is proportional to the volume of magnetic elements. Practical implementation with full electrical control via MTJs can be challenging due to the complexity of the stray field profile in the MTJ stack. Finally, an external clocking field is usually needed to assist the switching of the output.

An STMG device may also be based on spin orbit torque driven domain wall motion. In this concept, logic operation requires sending electrical current from every input arm to induce domain wall motion in a logic circuit. This operation scheme leads to a large current distribution in the output arm. As a result, it causes a failure mode of the majority operation due to random domain wall nucleation by Joule heating at the output and consequently reduces the reliability of the device.

An STMG device may also be based on spin orbit torque (SOT) driven domain wall motion and chiral coupling induced domain wall inversion. Chiral coupling between out-of-plane and in-plane magnetic regions in a single magnetic layer via strong Dzyaloshinskii-Moriya interaction (DMI) at the interface of the ferromagnetic layer and a heavy metal has been proposed and experimentally studied by ETH and PSI (see, e.g., Luo et al., Science 363.6434 (2019): 1435-1439). Experimental demonstration of this concept has been performed on samples where a selective oxidization process has been used to produce magnetic out-of-plane and in-plane regions in a single magnetic layer. However, this fabrication process poses some challenges to implement with MTJs for full electrical control of nanoscale devices due to the complex multilayer magnetic structures of a MTJ stack. Reconfigurable domain wall logic devices based on the chiral coupling induced domain wall inverter have been experimentally demonstrated by ETH and PSI (Luo et al. Nature 579.7798 (2020): 214-218). This concept uses a common SOT current line to push the domain wall motion for logic operation, solving the current crowding issue at the output but leading to delays due to the different speeds of domain wall motion at every input. Indeed, in this design, the current produces different SOT on the domain walls at different input arms due to the orientation of each input with respect to the SOT line. As a result, it leads to different speeds of domain wall motion from different inputs. Therefore, a long delay is expected to complete the logic operation. This device concept also requires additional energy to push the domain wall through the in-plane region and nucleate a domain on the other side of this region. Compared to conventional integration schemes of STMG devices, additional mask sets and integration processes are needed to implement an in-plane region to enable chiral coupling between two out-of-plane magnetic regions of the domain wall conduit.

The present disclosure will be described with respect to particular embodiments and with reference to certain drawings, but the disclosure is not limited thereto. The drawings described are only schematic and are non-limiting. In the drawings, the size of some of the elements may be exaggerated and not drawn to scale for illustrative purposes. The dimensions and the relative dimensions may not correspond to actual reductions to practice.

The terms first, second, and the like in the description and in the claims, are used for distinguishing between similar elements and not necessarily for describing a sequence, either temporally, spatially, in ranking, or in any other manner. It is to be understood that the terms so used are interchangeable under appropriate circumstances and that the embodiments described herein are capable of operation in other sequences than described or illustrated herein.

Moreover, the terms top, under, and the like in the description and the claims are used for descriptive purposes and not necessarily for describing relative positions. It is to be understood that the terms so used are interchangeable under appropriate circumstances and that the embodiments described herein are capable of operation in other orientations than described or illustrated herein.

It is to be noticed that the term “comprising,” used in the claims, should not be interpreted as being restricted to the features, elements, or steps listed thereafter; it does not exclude other features, elements, or steps. It is thus to be interpreted as specifying the presence of the stated features, integers, steps, or components as referred to, but does not preclude the presence or addition of one or more other features, integers, steps, or components, or groups thereof. Thus, the scope of the expression “a device comprising A and B” should not be limited to devices consisting only of components A and B. Rather, it should be interpreted to mean that the only required components of the device are A and B.

Reference throughout this specification to “one embodiment” or “an embodiment” means that a particular feature, structure, or characteristic described in connection with the embodiment is included in at least one embodiment. Thus, appearances of the phrases “in one embodiment” or “in an embodiment” in various places throughout this specification are not necessarily all referring to the same embodiment but may refer to different embodiments or the same embodiment. Furthermore, the particular features, structures, or characteristics may be combined in any suitable manner, as would be apparent to one of ordinary skill in the art from this disclosure, in one or more embodiments.

Similarly it should be appreciated that in the description of example embodiments, various features are sometimes grouped together in a single embodiment, figure, or description thereof for the purposes of streamlining the disclosure and aiding in the understanding of one or more of the various inventive aspects. This method of disclosure, however, is not to be interpreted as reflecting an intention that more features than are expressly recited in each claim are required. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment.

Furthermore, while some embodiments described herein include some but not other features included in other embodiments, combinations of features of different embodiments are meant to be within the scope of the disclosure, and form different embodiments, as would be understood by those in the art. For example, in the following claims, any of the claimed embodiments can be used in any combination.

In the description provided herein, numerous specific details are set forth. However, it is understood that embodiments of the disclosure may be practiced without these specific details. In other instances, well-known methods, structures, and techniques have not been shown in detail in order not to obscure an understanding of this description.

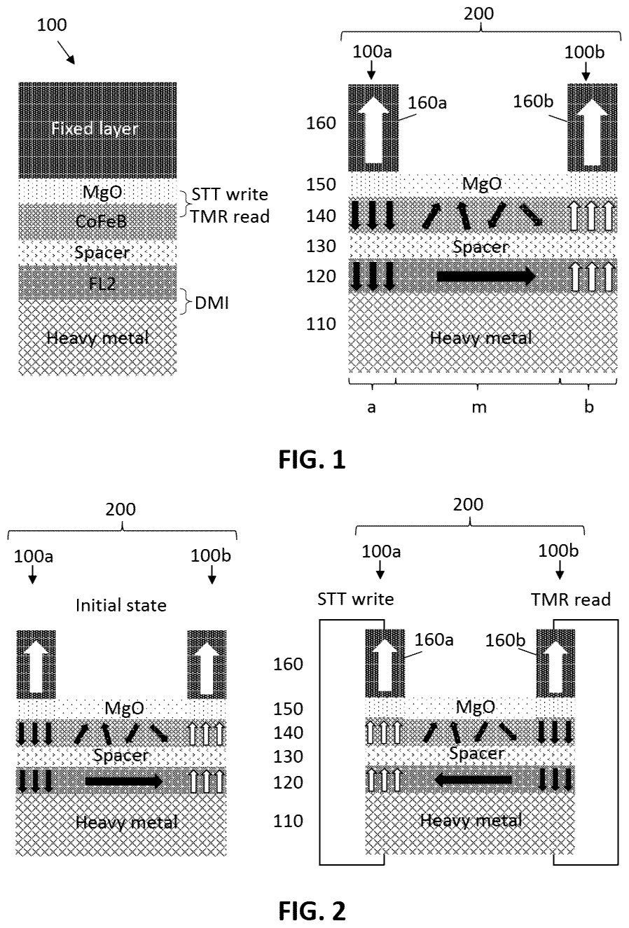

In a first aspect, embodiments of the present disclosure relate to a magnetic device 200 comprising at least two MTJ pillars 100, as shown in FIG. 1. In the illustrated embodiment, each of the MTJ pillars 100a, 100b comprises:
a heavy metal layer portion 110a, 110b,
a second free magnetic layer portion 120a, 120b on the heavy metal layer portion 110a. 110b,
a spacer portion 130a, 130b on the second free magnetic layer portion 120a, 120b,
a first free magnetic layer portion 140a, 140b on the spacer portion 130a, 130b,
a tunnel barrier layer portion 150a, 150b on the first free magnetic layer portion 140a, 140b, and
a fixed magnetic layer portion 160a, 160b on the tunnel barrier layer portion 150a. 150b.

At least the heavy metal layer portions 110a, 110b, the second free magnetic layer portions 120a, 120b and the spacer portions 130a, 130b may extend between the MTJ pillars 100a, 100b through an interconnecting heavy metal layer portion 110m, an interconnecting second free magnetic layer portion 120m, and an interconnecting spacer portion 130m, respectively, thereby forming a heavy metal layer 110, a second free magnetic layer 120, and a spacer layer 130. Each of the heavy metal layer 110, the second free magnetic layer 120 and the spacer layer 130 can thus form a continuous layer laterally extending across the at least two MTJ pillars 100a, 100b.

The interconnecting second free magnetic layer portion 120m can have an in-plane magnetization, and the second free magnetic layer portions 120a, 120b of the MTJ pillars 100 can have an out-of-plane magnetization.

In some embodiments, the first free magnetic layer portions 140a, 140b may extend between the MTJ pillars 100 through an interconnecting first free magnetic layer portion 140m, thereby forming a first free magnetic layer 140.

In some embodiments, the tunnel barrier layer portions 150a, 150b may extend between the MTJ pillars 100 through an interconnecting tunnel barrier layer portion 150m, thereby forming a tunnel barrier layer 150. In some embodiments, the tunnel barrier layer 150 may comprise MgO.

In some embodiments, the first free magnetic layer portions 140a, 140b, the second free magnetic layer 120, and, if present, the interconnecting first free magnetic layer portion 140m may be made of ferromagnetic material.

In some embodiments, the first free magnetic layer portions 140a, 140b, and, if present, the interconnecting first free magnetic layer portion 140m may include or be formed of CoFeB. It is thereby an advantage of some embodiments that a good TMR signal and low STT switching current can be obtained via the MTJs.

Some embodiments relate to a logic device 300 which may include a magnetic device 200 according to some embodiments. The magnetic device may include at least four MTJ pillars, of which an odd number of MTJ pillars may be used as input and one of the MTJ pillars may be used as output.

In some embodiments, chiral coupling between perpendicular MTJs may be implemented for full electrical control of spintronic minority gate devices. Via STT write, the logic inputs may be provided and via TMR readout, the logic output can be read.

Chiral coupling between perpendicular MTJs interconnected via the interconnecting second free magnetic layer portion 120m may be induced by strong DMI between the free layer and the common heavy metal layer 110 underneath. In a simple picture, the magnetization of the free layer at the first perpendicular MTJ may be strongly coupled with the second MTJ in an anti-parallel arrangement due to the chiral coupling via the in-plane region as shown in the right stack of FIG. 1. In this drawing, the arrows represent the direction of the magnetization in each layer of the MTJ stack. The arrows in the interconnecting first free magnetic layer portion 140m represent the magnetic state in this portion, which can be damaged during the device integration process.

The left figure of FIG. 1 shows a schematic drawing of a hybrid free layer stack design which may be used to implement chiral coupling between 2 MTJ pillars via an interconnecting free layer 120m as shown in the right figure. The hybrid free layer design may include an interexchange layer, also referred to as a spacer 130, sandwiched in between the first free magnetic layer 140 (e.g., a CoFeB-based free layer) and the second free magnetic layer 120 (FL2) as schematically shown. The role of the first free magnetic layer 140 may be to provide a good TMR signal and low STT switching current via MTJs. The spacer layer 130 may be provided to make a structural transition between the first free magnetic layer 140 and the second free magnetic layer 120. The spacer layer 130 may, for example, comprise Ta, W, Nb, Mo and/or a heavy-metal-transition-metal alloy, such as TaCoFeB, WCoFeB. The thickness of the interexchange layer 130 can be tuned such that the first free magnetic layer 140 (e.g., comprising CoFeB) and the second free magnetic layer 120 are ferromagnetically (FM) coupled through exchange interaction. The thickness of the spacer layer 130 may for example range between about 0.1 mu and about 1 nm or more preferably between about 0.2 and about 0.4 nm.

The thickness of the fixed magnetic layer 160 may for example range between about 10 nm and about 25 nm. The thickness of the tunnel barrier layer 150 may for example range between about 0.8 nm and about 2 nm. The tunnel barrier layer may for example be a MgO layer. The thickness of the first free layer 140 may for example range between about 0.5 nm and about 1 nm. The thickness of the second free layer 120 may for example range between about 0.5 mu and about 1 nm. The thickness of the heavy metal layer 110 may for example range between about 1 nm and about 10 nm, preferably between about 2.5 nm and about 3.5 um.

In some embodiments, the magnetic state of the interconnecting second free magnetic layer portion 120m can be tuned from out-of-plane to in-plane by ion beam etching and/or ion irradiation.

In some embodiments, the second free magnetic layer 120 may comprise Co, Fe, CoFeB, and/or any combination thereof.

In some embodiments, the heavy metals with large spin orbit coupling may comprise any of Ir, W, Hf, Pt, Ta and may be the source providing the DMI on the second free magnetic layer 120.

In some embodiments, fabrication of chiral MTJs may be done by controlling the in-plane magnetic state of the second free magnetic layer portion 120m via ion beam etching and/or ion irradiation processes. The out-of-plane magnetization state of the free layer portions 120a. 120b underneath of the MTJ pillars 100 may be maintained during the process due to the protection of a hard mask against etching/irradiation processes.

Chiral coupling may be driven by the DMI originated from the interface of the second free layer 120 and the heavy metal layer 110. The strength and sign of chiral coupling can be controlled by the nature of DMI at the interface of the second free layer 120 and the heavy metal layer 110 in the hybrid free layer design.

The magnetization state of the MTJs 100 and the interconnecting in-plane free layer 120m may be strongly correlated in order to minimize the DMI energy that originates from the interface of the second free magnetic layer 120 and the heavy metal layer 110.

In an equilibrium state, the magnetization direction of the MTJs 100 and the in-plane interconnecting free layer 120m may have a unique chirality that is fixed by the nature of the DMI. Thus, the magnetization state of the MTJs and the interconnecting in-plane free layer 120m can be mutually switched. As a result, the magnetization state of an MTJ pillar 100a can be laterally controlled by STT-induced switching at the adjacent MTJ pillar 100b.

The left stack of FIG. 2 shows the initial state of a basic building block of chiral MTJs according to some embodiments. STT may be applied at the first MTJ pillar 100a to locally switch its magnetization state from an anti-parallel state to parallel state. The right device of FIG. 2 presents chiral inverter operation where STT is used to switch the magnetic state of MTJ pillar 100a. Because of chiral coupling, the magnetization of the interconnecting in-plane region (e.g., the interconnecting second free magnetic layer portion 120m) and of the second MTJ pillar 100b may be naturally switched in the opposite direction in order to minimize the DMI energy. The change of magnetization state at the second MTJ pillar can be electrically detected by TMR reading. Thus, an inverter or NOT logic gate may be obtained. An inverter or NOT logic gate may be a basic building block of any logic device.

In some embodiments, in a logic device 300, the MTJ pillars may be organized in a star or T configuration wherein a plurality of arms may extend from a central point. The interconnecting second free magnetic layer portions 120m may form the arms of the star. MTJs 100 which are used as input may be positioned at outer ends of the arms and the MTJ which is used as output may be positioned at the central point of the star. The logic device may include an odd number of input MTJ pillars. Thus, a minority logic gates operation can be obtained. This may correspond to a majority gate combined with an inversion step.

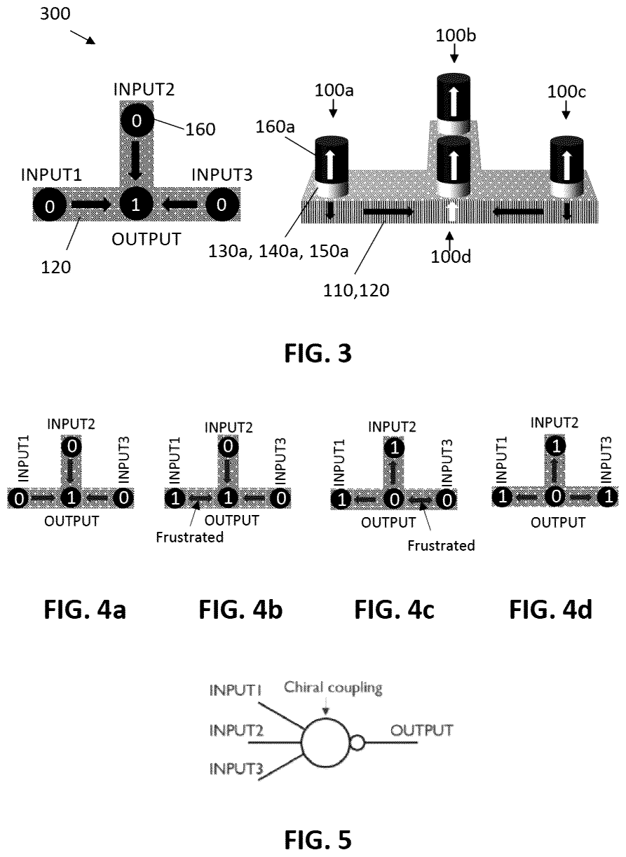

An example of such a logic device is shown in FIG. 3. The left schematic drawing shows a top view and the right schematic drawing shows a 3D-view of the stack. In this device, the logic state of inputs and outputs are fully electrically controlled via MTJs. In this example, chiral switching driven minority gate operation consists of 3 MTJ inputs and 1 MTJ output which are interconnected by an in-plane free layer. This corresponds with a combination of 3 inverters sharing a common output MTJ. The most basic design of the logic device is in a T-shape structure as in FIG. 3. From top to bottom, the fixed magnetic layer portion 160a, the tunnel barrier layer portion 150a, the first free magnetic layer portion 140a, the spacer portion 130a are shown (the latter three are shown as one layer to simplify the figure). Furthermore, the second free magnetic layer 120 and the heavy metal layer 110 are shown (these are also shown as one layer to simplify the picture). The second free magnetic layer portions under the pillars have an out-of-plane magnetization. The interconnecting second free magnetic layer portions between the pillars have an in-plane magnetization.

In this device, the logic state is encoded in the magnetization state of the free layer underneath the pillars. The magnetization direction of the MTJs and the in-plane interconnecting free layer are fixed by the nature of the DMI at the interface between the free layer and the heavy metal.

In some embodiments, STT may be used during operation to drive the switching of the free layer underneath the input pillar 100a, 100b, 100c, which may include switching of the interconnecting free layer due to chiral coupling. The logic state of the output, which may be defined by the majority states of logic inputs, may be detected by TMR at the output MTJ 100d. Therefore, this logic gate can be reconfigured as a minority operation where the logic state of inputs and outputs are fully electrically controlled via MTJs. In such a minority logic gate the output may only be switched if more than 50% of the inputs are switched. In some embodiments, the output may only be switched if majority states of logic inputs are switched. Since the input and output may always be in opposite logic states, this majority operation may form a minority logic gate.

In some embodiments, a logic device according to the present disclosure can have fast operation and low energy consumption compared to devices which are based on SOT driven domain wall motion. Indeed, the operation of chiral logic devices according to some embodiments may no longer be based on the SOT driven domain wall motion, avoiding issues related to domain wall pinning and the use of in-plane current.

In some embodiments, the magnetic state of the interconnecting free layer is precisely controlled to be in-plane. No additional mask or processes are needed to define the in-plane region.

FIGS. 4a-4d present the representative operation of a logic device comprising three input MTJs and one output MTJ according to some embodiments.

FIG. 4a shows the initial state, the logic state of the inputs is set to be 0 and thus the logic output is naturally 1 due to the chiral coupling.

In FIG. 4b, STT is applied at one of the inputs, thus INPUT1 is switched from 0 to 1. In this operation, the logic output may be maintained at logic state 1 since it is set by chiral coupling from INPUT2 and the INPUT3. The magnetic state of the in-plane free layer between INPUT1 and OUTPUT may be in a frustrated state.

In FIG. 4c, STT is applied at 2 inputs. INPUT1 and INPUT2 are switched from 0 to 1. In this operation, the logic state of OUTPUT may be switched from 1 to 0 since it is driven by chiral coupling from INPUT1 and INPUT2. The magnetic state of the in-plane free layer between INPUT3 and OUTPUT may be in a frustrated state.

In FIG. 4d, STT is applied at all 3 inputs. In this example all INPUTs are switched from 0 to 1. In this operation, the logic state of the OUTPUT may be switched from 1 to 0 since it is driven by chiral coupling from all the inputs. There may not be a frustrated state of the in-plane free layer in this operation.

By the combination of all possible logic inputs, a logic truth table for the reconfigurable NAND and NOR logic operations can be built based on the logic device, according to some embodiments.

FIG. 5 presents the schematic of a minority logic gate driven by chiral coupling according to some embodiments. The truth table of this logic gate with 3 inputs is shown below.

| INPUT1 | INPUT2 | INPUT3 | OUTPUT |
|---|---|---|---|
| 0 | 0 | 0 | 1 |
| 0 | 0 | 1 | 1 |
| 0 | 1 | 0 | 1 |
| 0 | 1 | 1 | 0 |
| 1 | 0 | 0 | 1 |
| 1 | 0 | 1 | 0 |
| 1 | 1 | 0 | 0 |
| 1 | 1 | 1 | 0 |

Some embodiments relate to a method 400 for manufacturing a magnetic or logic device which comprises at least two MTJ pillars.

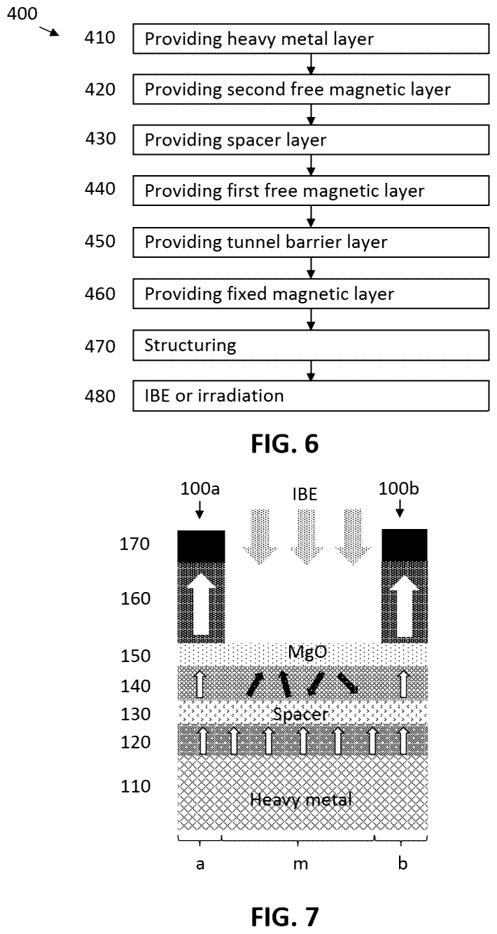

An exemplary flow chart of such a method 400 is shown in FIG. 6. The method comprises:
providing 410 a heavy metal layer 110,
providing 420 a second free magnetic layer 120 on top of the heavy metal layer 110,
providing 430 a spacer layer 130 on the second free magnetic layer 120,
providing 440 a first free magnetic layer 140 on the spacer layer 130,
providing 450 a tunnel barrier layer 150 on the first free magnetic layer 140,
providing 460 a fixed magnetic layer 160 on the tunnel barrier layer 150, and
structuring 470 the fixed magnetic layer 160 such that fixed magnetic layer portions 160a, 160b of the MTJ pillars 100 are remaining.

Structuring may be done by removing parts of the fixed magnetic layer 160. Structuring may be achieved by, for example, etching. An example thereof is illustrated in FIG. 7. In this example a hard mask 170 is provided that may be used to pattern the pillars, and the pillars may be obtained by ion beam etching. By structuring 470, the second free magnetic layer 120 may be subdivided into second free magnetic layer portions 120a, 120b underneath the fixed magnetic layer portions 160a, 160b, and an interconnecting second free magnetic layer portion 120m between two MTJ pillars 100. The second free magnetic layer portions 120a, 120b may be out-of-plane magnetic regions. In some embodiments, the obtained pillars may for example have a width between about 10 un and about 100 nm, for example about 50 nm. The pillar width may be limited to a maximum because it may become harder to switch if the pillars are too large. The spacing between the pillars may for example range between about 20 nm and about 100 nm, before example about 50 nm. The maximum spacing may be such that the in-plane magnetization can be flipped entirely. The maximum spacing may be limited by the distance over which chiral interaction can be strong enough (for example, below about 100 nm).

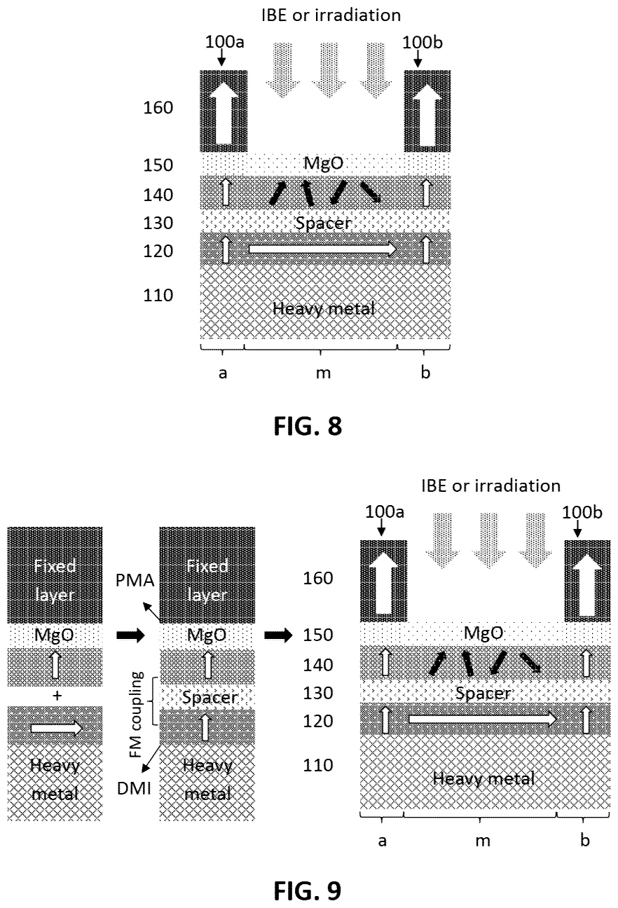

In some embodiments, ion beam etching (IBE) and/or ion irradiation processes 480 may be applied between the fixed magnetic layer portions 160a, 160b to convert the magnetic state of the interconnecting second free magnetic layer portion 120m from PMA to in-plane to enable chiral coupled MTJs devices. This is illustrated in FIG. 8, which shows that as a result of the IBE or irradiation, an in-plane magnetic state may be obtained for the interconnecting second free magnetic layer portion compared to the out-of-plane magnetization in FIG. 7.

Structuring may be done deeper into the layered stack, for example into the tunnel barrier layer 150, into the first free magnetic layer 140, and/or into the spacer layer 130.

In some embodiments, the first free magnetic layer portion may be perpendicularly magnetically anisotropic as a result interfacial PMA at the interface between the first free layer and the tunnel barrier layer (e.g., CoFeB/IMgO).

In some embodiments, the interconnecting second free magnetic layer portion may be designed to have an in-plane magnetic anisotropy as illustrated in FIG. 9. This may for example be achieved by tuning the thickness of the second free layer (which may for example be a Co layer).

Within an MTJ pillar, the PMA of the first free layer portion may enforce the PMA of the second free magnetic layer portion via ferromagnetic coupling of spacer material. In some embodiments, without the ferromagnetic coupling with an out-of-plane first free layer, the second free magnetic layer portion may have in-plane magnetization.

During the device fabrication process to pattern the MTJ pillars, the interface of the interconnecting tunnel barrier portion and the interconnecting first free magnetic layer portion may be damaged by ion beam etching or irradiation 480. This may lead to the loss of interfacial PMA of the interconnecting tunnel barrier/first free magnetic layer. Without any support for the PMA of the tunnel barrier/first free magnetic layer, the interconnecting second free magnetic layer portion 120m/interconnecting heavy metal layer portion 110m may have in-plane magnetization.

Using such a method, according to some embodiments, chiral coupling may be implemented in interconnected MTJs using a hybrid free layer stack design for full electrical control of nanoscale spintronic devices. In some embodiments, logic devices can be scalable and implementable using MRAM technology.

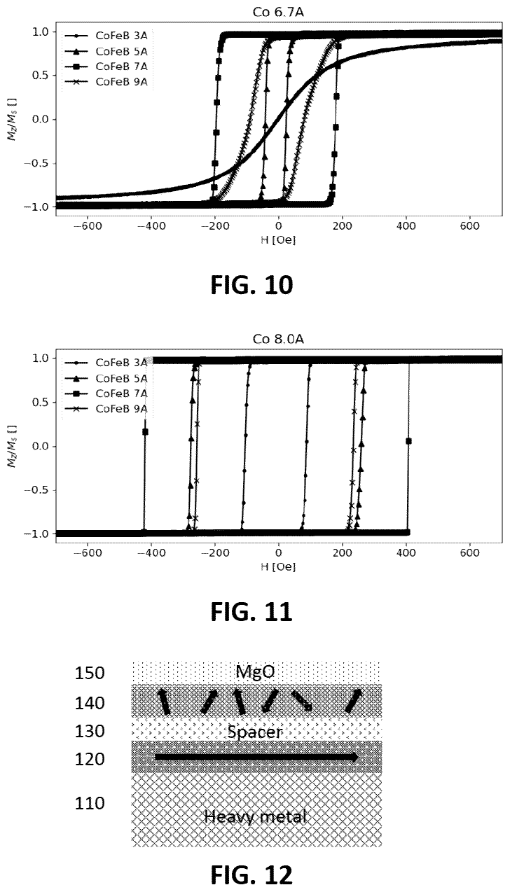

The graphs of FIG. 10 and FIG. 11 show how the MTJ stacks can be designed. In both graphs, the curves show M_{z}/Mₛ as a function of a magnetic field H for different thicknesses of the first free magnetic layer portion (0.3 nm, 0.5 nm, 0.7 nm, 0.9 nm). In FIGS. 10 and 11, M_{z} is the measured magnetization in the z-direction (orthogonal to the layers of the MTJ stack) and Mₛ is the saturation magnetization. For both graphs, the first free magnetic layer is a CoFeB layer, the second free magnetic layer is a Co layer, and the heavy metal layer is a Pt layer.

For the curves in FIG. 10, the thickness of the second free magnetic layer is 0.67 um. Without ferromagnetic coupling, this results in an in-plane magnetization of the Pt/Co. With ferromagnetic coupling with the first free magnetic layer, the stack is perpendicularly magnetically anisotropic for a limited number of thicknesses of the first free magnetic layer (not anymore for a thickness of the first free magnetic layer of 0.3 nm). The stack is only perpendicularly magnetically anisotropic if CoFeB/MgO is perpendicularly magnetically anisotropic. The optimal PMA is, in this example, obtained with a thickness of the first free magnetic layer of 0.7 nm.

For the curves in FIG. 11, the thickness of the second free magnetic layer is 0.8 nm. In this case the stack is perpendicularly magnetically anisotropic for all tested thicknesses of the first free magnetic layer. Between the different thicknesses, the coercivity changes, but the squareness of the loop is similar for each of them.

In some embodiments, the thickness of the second free magnetic layer may be selected such that it has an in-plane magnetic state in the absence of a ferromagnetic coupling with a first free magnetic layer portion which is perpendicularly magnetically anisotropic, and such that the second free magnetic layer is perpendicularly magnetically anisotropic in the presence of ferromagnetic coupling with a first free magnetic layer portion which is perpendicularly magnetically anisotropic. The optimal thicknesses may be dependent on the material choices and can be designed using magnetic hysteresis loop measurements as illustrated in FIG. 10 and FIG. 11.

As explained earlier, the in-plane magnetization of the interconnecting second free magnetic layer portion can be obtained by IBE or irradiation on the exposed part of the tunnel barrier layer between the pillars. This may lead to the loss of interfacial PMA of the interconnecting tunnel barrier/first free magnetic layer and as a result thereof to in-plane magnetization of the interconnecting second free magnetic layer portion. This can be validated using the control structure illustrated in FIG. 12. Using such a control structure, the in-plane magnetic state of the control structure can be measured using anisotropic magnetoresistance, which is well known in spintronics. This allows validation of the process to control the magnetic state from PMA to in-plane magnetization.

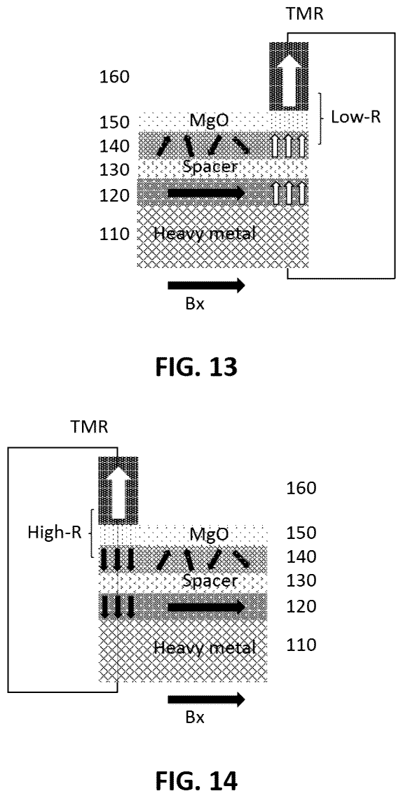

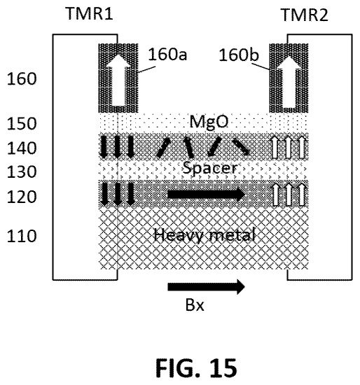

Chiral coupling using in-plane magnetic field Bₓ can be validated using other control structures. Examples are illustrated in FIG. 13, FIG. 14, and FIG. 15. FIG. 13 and FIG. 14 show stacks wherein one MTJ pillar is coupled with an extended in-plane free layer. In case of a saturated state of the extended free layer and in case the chirality exists, the resistance state of the MTJ pillar in FIG. 13 is opposite from the resistance state in FIG. 14. In FIG. 13, the resistance state is a low resistance state, and in FIG. 14, the resistance state is a high resistance state. By measuring the resistance, the existence of chiral coupling can be verified. The resistance state may be reversed when reversing the direction of the in-plane magnetic field.

In a magnetic device with two MTJ pillars, chiral coupling using an in-plane magnetic field can be measured. This is illustrated in FIG. 15. In the illustration, the in-plane magnetic state points in the same direction as the in-plane field Bₓ. If the chiral coupling is maintained, the resistance state of the MTJ may be changed by flipping the magnetic state of the interconnecting second in-plane free layer.

Using an STT driven chiral switching process, full electrical control of a logic device in accordance can be achieved.

It may be advantageous that the logic minority operation of the logic device is no longer based on the motion of domain walls. Therefore, it offers very fast operation and very low energy consumption and overcomes the challenges related to domain wall motion and current crowding in the current design of STMG devices. In a logic device according to embodiments of this disclosure, the operation speed only depends on STT switching and chiral switching times.

What is claimed is:

1. A magnetic device comprising:
at least two magnetic tunnel junction pillars, each magnetic tunnel junction pillar comprising a heavy metal layer portion, a second free magnetic layer portion on the heavy metal layer portion, a spacer portion on the second free magnetic layer portion, a first free magnetic layer portion on the spacer portion, a tunnel barrier layer portion on the first free magnetic layer portion, and a fixed magnetic layer portion on the tunnel barrier layer portion,
wherein at least the heavy metal layer portions, the second free magnetic layer portions and the spacer portions extend between the magnetic tunnel junction pillars through an interconnecting heavy metal layer portion, an interconnecting second free magnetic layer portion and an interconnecting spacer portion, respectively, thereby forming a heavy metal layer, a second free magnetic layer, and a spacer layer, and
wherein the interconnecting second free magnetic layer portion has an in-plane magnetization and the second free magnetic layer portions of the magnetic tunnel junction pillars have an out-of-plane magnetization.

2. The magnetic device of claim 1, wherein the first free magnetic layer portions extend between the magnetic tunnel junction pillars through an interconnecting first free magnetic layer portion to form a first free magnetic layer.

3. The magnetic device of claim 2, wherein the tunnel barrier layer portions extend between the magnetic tunnel junction pillars through an interconnecting tunnel barrier layer portion to form a tunnel barrier layer.

4. The magnetic device of claim 1, wherein the first free magnetic layer portions comprise a first ferromagnetic material and the second free magnetic layer comprises a second ferromagnetic material.

5. The magnetic device of claim 2, wherein the first free magnetic layer portions comprise a first ferromagnetic material, wherein the second free magnetic layer comprises a second ferromagnetic material, and wherein the interconnecting first free magnetic layer portion comprises a third ferromagnetic material different from the first and second ferromagnetic materials.

6. The magnetic device of claim 1, wherein the first free magnetic layer portions comprise CoFeB.

7. The magnetic device of claim 2, wherein the first free magnetic layer portions and the interconnecting first free magnetic layer portion comprise CoFeB.

8. The magnetic device of claim 1, wherein the second free magnetic layer comprises Co, Fe, CoFeB, or any combination thereof.

9. The magnetic device of claim 1, wherein the heavy metal layer comprises Ir, W, Hf, Pt, Ta, or any combination thereof.

10. The magnetic device of claim 1, wherein the spacer layer comprises Ta, W, Nb, Mo, a heavy-metal-transition-metal alloy, or any combination thereof.

11. The magnetic device of claim 10, wherein the heavy-metal-transition-metal alloy comprises TaCoFeB, WCoFeB, or both.

12. The magnetic device of claim 1, wherein a thickness of the spacer layer is from about 0.1 nm to about 1 nm.

13. The magnetic device of claim 1, wherein the tunnel barrier layer portions comprise MgO.

14. The magnetic device of claim 3, wherein the interconnecting tunnel barrier layer portion and tunnel barrier layer portions comprise MgO.

15. A logic device comprising the magnetic device according to claim 1, wherein the at least two tunnel junction pillars include at least four magnetic tunnel junction pillars.

16. The logic device of claim 15, wherein the magnetic tunnel junction pillars are organized in a star configuration comprising a plurality of arms extending from a central point, wherein the interconnecting second free magnetic layer portions form the arms of the star, and wherein input magnetic tunnel junctions are positioned at outer ends of the arms, and an output magnetic tunnel junction is positioned at the central point of the star.

17. A method of manufacturing a magnetic or logic device comprising at least two magnetic tunnel junction pillars, the method comprising:
providing a heavy metal layer;
providing a second free magnetic layer on top of the heavy metal layer;
providing a spacer layer on the second free magnetic layer;
providing a first free magnetic layer on the spacer layer;
providing a tunnel barrier layer on the first free magnetic layer;
providing a fixed magnetic layer on the tunnel barrier layer;
structuring the fixed magnetic layer such that fixed magnetic layer portions of the magnetic tunnel junction pillars are remaining, wherein structuring comprises subdividing the second free magnetic layer into a plurality of portions including second free magnetic layer portions underneath the fixed magnetic layer portions and an interconnecting second free magnetic layer portion extending between two magnetic tunnel junction pillars, and wherein the second free magnetic layer portions are out-of-plane magnetic regions,
ion beam etching and/or ion irradiating the interconnecting second free magnetic layer portion between the fixed magnetic layer portions such that the interconnecting second free magnetic layer portion has an in-plane magnetic state.

18. The method of claim 17, wherein structuring further comprises subdividing the tunnel barrier layer into a plurality of portions.

19. The method of claim 17, wherein structuring further comprises subdividing the first free magnetic layer into a plurality of portions.

20. A method of using the magnetic device of claim 1, the method comprising:
switching, using spin torque transfer, the first free magnetic layer and the second free magnetic layer of a magnetic tunnel junction pillar of the plurality of magnetic tunnel junction pillars, wherein the switching causes switching of the interconnect second free layer portion due to chiral coupling; and
reading, using tunneling magnetoresistance, a magnetization of the first free magnetic layer portion of an other magnetic tunnel junction pillar of the plurality of magnetic tunnel junction pillars.
